(19) United States
(12) Patent Application Publication
(10) Pub. No.: US 2007/0028837 A1
(43) Pub. Date: Feb. 8, 2007

(54) AN APPARATUS FOR PLASMA TREATMENT

(75) Inventors: Yongbai YIN, Sydney, NSW (AU); Marcela Bilek, Sydney, NSW (AU); David McKenzie, Sydney, NSW (AU); Anne Gerd Imenes, Sydney, NSW (AU)

Correspondence Address: GANZ LAW, P.C., P O BOX 2200, HILLSBORO, OR, 97123, US

(73) Assignee: THE UNIVERSITY OF SYDNEY, Sydney, NSW (AU)

(21) Appl. No.: 10/598,055

(22) PCT Filed: Feb. 21, 2005
(86) PCT No.: PCT/AU05/00227

§ 371 Date: Oct. 17, 2006

(30) Foreign Application Priority Data
Feb. 20, 2004 (AU) 2004900864

(51) Int. Cl. C23C 16/00

(52) U.S. Cl. 118/715

(57) ABSTRACT

The present invention provides an apparatus (10) for plasma treatment of a substrate surface (16). The apparatus comprises a plasma source (12) for generating a plasma and a plasma-control electrode (14). The apparatus further comprises a drive means for effecting a relative movement between the plasma-control electrode (14) and the plasma source (12) or of the plasma-control electrode (14) and the plasma source (12) relative to the substrate (16). The plasma-control electrode (14) is located adjacent the substrate (16) to facilitate treatment of the substrate surface (16) in a controlled manner.

### FIELD OF THE INVENTION

The present invention relates to an apparatus for plasma treatment of a substrate surface.

### BACKGROUND OF THE INVENTION

Plasma treatment of surfaces is used for fabrication in a variety of different areas of technology. For example, plasma treatment is used in microelectronics, optics and photonics to coat surfaces of substrates or to etch structures into the substrates. Plasma treatment may be used to coat substrates with films or to etch regions or structures into the substrates. In general, plasma treatment may be characterised by resultant surface properties such as: thickness, density, refractive index, microstructure and composition. The surface properties obtained depend on the type of plasma treatment and degree of control.

It is often desired that surface coatings are as uniform as possible. For example, for photonics applications, such as dense wavelength division multiplexing (DWDM) filters, it is desired that a thickness of coating does not vary more than 0.05% along the coated substrate.

In general it is very difficult to generate a plasma that has a uniform density profile. The density profile of the plasma depends on many parameters such as gas flow rate, gas flow distribution, gas ratios, pumping rate, plasma energy and geometrical constraints of the source that generates the plasma. The generated plasma usually has a main plasma region and plasma outside the main plasma region often reduces the treatment quality and may cause porous areas in film coatings, poor adhesion on the substrate or surface roughness.

Attempts have been made to design plasma sources that provide for improved understanding and control of the plasma. For example, plasma sources have been designed that comprise electrodes having a large number of gas outlet openings distributed evenly over their surface, not dissimilar to a conventional “showerhead”, and arranged so that a gas flow distributed over the surface results in the ability to produce a more uniform surface density profile. However, treatment of large substrates is difficult and requires large and very expensive systems.

Further, for some applications, such as selected optical applications, it is desired to coat surfaces so that the coating has one or more surface properties such as thickness, density, refractive index, that vary in a predetermined manner. For example, these properties may also include graded or tapered profiles. Such coatings having controlled properties are even more difficult to produce.

### SUMMARY OF THE INVENTION

The present invention provides in a first aspect an apparatus for plasma treatment of a substrate surface comprising:

a plasma source for generating a plasma,

a plasma-control electrode, and

a drive means for effecting a relative movement between the plasma-control electrode and the plasma source,

wherein in use the plasma-control electrode is located adjacent the substrate to facilitate treatment of the substrate surface in a controlled manner.

The drive means typically also effects in use a relative movement between the substrate and the plasma source. The plasma-control electrode and the substrate may have substantially the same size.

In one specific embodiment the substrate and the plasma-control electrode are stationary and the plasma source is driven to effect the relative movement. In an alternative embodiment the plasma source is stationary and in use both the substrate and the plasma-control electrode are driven.

In a further variation, the plasma source is driven and both the substrate and the plasma-control electrode are in use driven relative to the driven plasma source. For example, the plasma-control electrode and the substrate may in use be rotated and the plasma source may in use be scanning. Alternatively, the plasma-control electrode and the substrate may in use be scanning and the plasma source may in use be rotating.

The present invention provides in a second aspect an apparatus for plasma treatment of a substrate surface comprising:

a plasma source for generating a plasma,

a plasma-control electrode, and

a drive means for effecting a relative movement of the plasma-control electrode and the plasma source relative to the substrate,

wherein in use the plasma-control electrode is located adjacent the substrate to facilitate treatment of the substrate surface in a controlled manner.

In one specific embodiment of the second aspect of the present invention the plasma source and the plasma-control electrode are stationary and the substrate is in use driven to effect the relative movement. In an alternative embodiment the substrate is in use stationary and the plasma source and the plasma-control electrode are driven. In this case the plasma source and the plasma-control electrode typically are driven in a synchronised manner.

In a further variation of the second aspect of the present invention, the substrate is in use driven and both the plasma-control electrode and the plasma source are driven relative to the driven substrate. For example, the substrate may in use be rotated and both the plasma-control electrode and the plasma source may in use be scanning. Alternatively, the plasma-control electrode and the plasma source may in use be rotated and the substrate may in use be scanning.

The apparatus according to the first or the second aspect of the present invention have significant practical advantages. For example, the substrate may be larger than the diameter of the plasma. Because of the movement and because of the treatment facilitation by the plasma-control electrode, the local properties of the treated substrate surface are less dependent on the density profile of the plasma which improves a desired uniformity or non-uniformity of the surface treatment. Consequently deposition of coatings having desired uniform or non-uniform properties such as coating thickness, or any structural, mechanical, chemical, optical and electrical properties is facilitated.

The plasma-control electrode of the apparatus according to either aspect of the present invention typically is arranged for facilitating the controlled surface treatment by controlling an energy distribution of the plasma in the proximity of the surface. Typically the plasma-control electrode is arranged to control an energy of plasma ions impacting on the substrate.

For example, the surface treatment may be facilitated so that in use the surface is treated in a controlled and non-uniform manner. The apparatus may be arranged for coating the surface in a manner so that the coating has at least one of a non-uniform thickness, density and refractive index. The thickness, density or refractive index may be tapered along a length of the substrate. Alternatively, the surface treatment may be facilitated so that in use the surface is treated in a controlled and uniform manner. For example, the apparatus may be arranged for coating the surface in a manner so that the coating has at least one of a uniform thickness, density and refractive index.

The plasma-control electrode of the apparatus according to the first or the second aspect of the present invention may be positioned at any position that is adjacent the substrate. In one embodiment the plasma control electrode is positioned so that the substrate is located between the plasma source and the plasma-control electrode. This arrangement is particularly advantageous for controlling the plasma energy and thereby controlling the surface treatment. In one embodiment the substrate is positioned between the plasma-control electrode and the plasma source and on the plasma-control electrode. If the substrate is flat, the plasma-control electrode may also be flat. In general, the plasma-control electrode may have any shape and typically is shaped to approximate the shape of the substrate.

In another embodiment of the invention according to the first or the second aspect, the plasma-control electrode comprises apertures and may be a mesh. In this case the plasma-control electrode may be positioned between the plasma source and the substrate.

The apparatus according to the first or the second aspect of the present invention typically is arranged so that the controlled treatment of the surface is facilitated by controlling a velocity of the relative movement and whereby a local plasma treatment time per unit substrate area can be controlled.

The apparatus according to the first or the second aspect of the present invention typically comprises a guard wall that confines the plasma. The guard wall typically is positioned about the plasma source and may surround the plasma source. The guard wall may also be arranged to confine a flow of gas. The guard wall may comprise an electrically conductive material and a voltage potential may be applied to the guard wall that may further control properties of the plasma such as the confinement of the plasma.

Further, the apparatus may be arranged to generate an additional magnetic field, for example within the guard wall, that facilitates in controlling the plasma.

The guard wall typically confines the plasma to a main plasma region and reduces or avoids plasma formation outside the main plasma area. This has the particular advantage that adverse affects on a surface treatment quality due to plasma outside the main plasma area can be reduced or avoided.

The guard wall typically is positioned so that in use a gap is formed between the substrate and the guard wall. The guard wall typically is arranged for pumping a gas through the gap and towards the source electrode which facilitates confinement of the plasma. For example, a reactive gas may in use be pumped through the source with its exhaust affected by the gas pumped through the gap.

The plasma source of the apparatus according the first or the second aspect of the present invention typically is arranged to generate a reactive plasma in which the input gases form a chemical reaction product. In a specific embodiment the plasma source is arranged to generate a plasma enhanced reactive chemical vapour deposition process which deposits a coating onto the substrate.

For example, the plasma source may comprise a magnetron source, a cathodic arc source, a helicon plasma source with an antenna surrounding an insulating hollow cylinder or a hollow cathode source including a cylindrical or other hollow conductor. In a specific embodiment, at least one source electrode of the plasma source is cup-shaped and arranged to receive an rf voltage signal. The or each source electrode may have a gas inlet and may be arranged so that in use the plasma is generated within the cup-shaped electrode and is directed towards the substrate.

In an alternative embodiment, the or each source electrode, which may for example be one of two source electrodes, comprises a number of spaced apart gas outlets. In this case gas may be provided from each gas outlet which improves the uniformity of the plasma profile.

The apparatus according to the first or the second aspect of the present invention may further comprise a monitoring system that is arranged to monitor the plasma treated substrate. For example, if the substrate is larger than the plasma diameter, it is possible to monitor the treated substrate outside the plasma area quasi in situ to obtain information about the plasma treatment that may be used to improve and/or control the plasma treatment of the substrate.

As the guard wall further confines the plasma, the monitoring system is less effected by the plasma and more accurate monitoring is possible.

In one specific embodiment the monitoring system is an optical system that is arranged to irradiate the substrate with a broadband optical wavelength spectrum. In this embodiment, the monitoring system is also arranged to receive reflections from the plasma treated substrate which may be analysed to obtain information about properties of the plasma treated substrate such as the thickness of substrate coating, or optical, chemical or structural properties. For example, the monitoring system and the relative movement may be arranged so that the surface can be monitored during treatment but outside the plasma region. This may enable quasi real-time monitoring.

The present invention provides in a third aspect an apparatus for plasma treatment of a substrate surface comprising:

a plasma source for generating a plasma,

a drive means for effecting a relative movement of the substrate relative to the plasma source and

a guard wall positioned about the plasma source to confine the plasma,

wherein in use the relative movement effects treatment of the substrate in a predetermined manner and the guard wall confines the plasma.

The guard wall may be arranged to directly confine the plasma or to confine flow of gas and may surround the plasma source. The guard wall may comprise an electrically conductive material and a voltage potential may be applied to the guard wall that generates an electric field. The electrical field may be used to further confine the plasma and/or control properties of the plasma.

The guard wall typically is positioned so that in use a gap is formed between the substrate and the guard wall. The guard wall typically is arranged for pumping a gas through the gap and towards the plasma source. For example, a reactive gas may in use be pumped through the source and the gap via differential pumping.

Throughout this specification, the term “rf voltage” is used for voltages having any frequencies including extremely high or extremely low frequencies. Further, it is to be understood that alternatively the plasma source may be arranged for operation by a dc voltage.

The present invention provides in a fourth aspect a substrate that is plasma treated by the apparatus according to the first or second aspects of the present invention.

The invention will be more fully understood from the following description of specific embodiments. The description is provided with reference to the accompanying drawings.

### BRIEF DESCRIPTION OF THE DRAWINGS

FIG. 1 shows a cross-sectional representation of an apparatus for plasma treatment of a substrate surface according to a first specific embodiment of the present invention, and

FIG. 2 shows a cross-sectional representation of an apparatus for plasma treatment of a substrate surface according to a second specific embodiment of the present invention.

### DETAILED DESCRIPTION OF SPECIFIC EMBODIMENTS

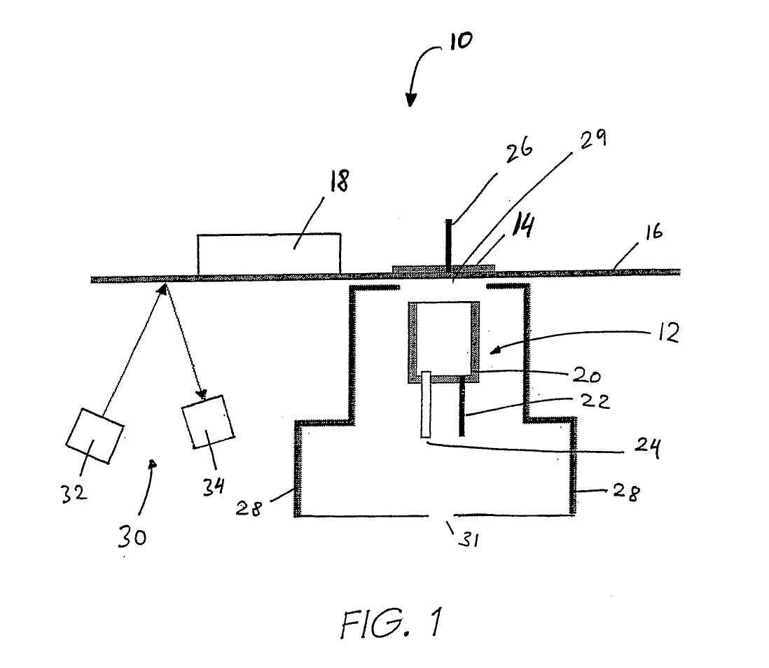

Initially referring to FIG. 1, an apparatus for plasma treatment of a substrate surface according to a first specific embodiment is now described. The apparatus 10 is positioned in a vacuum chamber which is not shown in FIG. 1. The apparatus 10 comprises a plasma source which includes a hollow cathode 12. The apparatus further comprises a plasma-control electrode 14. In variations of this embodiment a wall of the vacuum chamber can operate as a second source electrode. Substrate 16 is movable relative to the hollow cathode 12 and the plasma-control electrode 14 by drive 18. In operation a plasma enhanced reactive chemical vapour is generated by the hollow cathode 12 so that the substrate 16 is coated with a coating (not shown).

During operation, the drive 18 moves the substrate 16 relative to the plasma. The drive 18 is arranged to scan the substrate relative to hollow cathode 12 and the plasma-control electrode 14 in an XY coordinate system. The drive 18 can also be set up to rotate the substrate 16. In variations of this embodiment the plasma source may also be moved by one or more further drives (not shown) so that the plasma source is moved whilst the substrate is moved by the drive 18. For example the plasma source 12 can be scanned in a linear motion whilst the drive 18 rotates the substrate 16.

The movement of the plasma source 12 and the plasma-control electrode 14 can also be arranged so that their relative motion with respect to the substrate 16 is synchronous.

In other embodiments, discussed below, the plasma-control electrode 14 remains in a stationary position with respect to the substrate 16 whilst the plasma source 12 and/or the substrate 16 are moved. For example the plasma-control electrode 14 may be of the same dimensions as the substrate 16 and enable improved control of surface properties. Alternatively, or additionally the plasma-control electrode 14 can be a mesh that is positioned between the plasma source 12 and the substrate 16. In terms of relative movement, this mesh control electrode may be synchronised with the plasma source 12 or the substrate 16. The mesh has overcome potential problems associated with obtaining effective operation of a plasma-control electrode placed behind a thick substrate.

The flexibility of such relative arrangements between the plasma source 12, the substrate 16 and plasma-control electrode 14 is enabled by having controlled, localised plasma that is typically smaller than the dimensions of the substrate 16.

Various drive systems or combination of drive means can be used to effect the different types of relative movement.

In this embodiment a scanning or rotation speed of the substrate 16 that is effected by the drive 18 can be controlled. In this fashion the substrate 16 can be coated with a coating having predetermined properties, for example a thickness profile. Because the substrate 16 is moved relative to the plasma source 12 and the plasma-control electrode 14, a desired coating property is less dependent on the uniformity of the plasma. Therefore, it is possible to coat relatively large surfaces with a coating having predetermined properties such as a profiled thickness or a substantially uniform thickness.

In this embodiment the plasma source consists of a hollow cathode 12 having a cup-shaped electrode 20, an electrical connection 22 and a gas inlet 24. In use, an rf voltage having a frequency of a few 10 kHz is applied to electrical connection 22 and gas is directed into the cup shaped electrode 20 through gas inlet 24.

The plasma-control electrode 14 has an electrical connection 26 that is arranged to receive an rf voltage. In use, a plasma is generated by the hollow cathode 12 which is controlled and also supported by plasma-control electrode 14. For example, the energy of the plasma particles over the substrate 16 can be controlled by adjusting the rf voltages applied to the plasma-control electrode 14 and to the hollow cathode 12 relative to each other. The rf voltages can be adjusted so that they are of differing phase, amplitude or frequency.

The substrate 16 is positioned between the plasma-control electrode 14 and the hollow cathode 12. In this embodiment, the substrate 16 is positioned directly adjacent the plasma-control electrode 14. The substrate 16 and plasma-control electrode 14 can be arranged such that the plasma-control electrode 14 contacts the substrate 16.

The position of the plasma-control electrode 14 adjacent and behind the substrate 16 is particularly advantageous for controlling the plasma treatment properties on the substrate 16. In this embodiment the plasma-control electrode 14 has a shape that approximates that of the substrate 16; both the plasma-control electrode 14 and the substrate 16 have substantially flat contact surfaces.

In alternative embodiments the substrate 16 may have an arc shaped cross-section or any other cross-sectional shape and the plasma-control electrode 14 typically is shaped to approximate the shape of that substrate 16. In other embodiments the plasma-control electrode 14 may have any suitable shape that enables to facilitate control of the surface treatment. Further, the apparatus may comprise more than one plasma-control electrode and both the shape and the numbers of the plasma-control electrodes may be selected to achieve the desired controlled surface treatment.

The plasma-control electrode 14 may be connected to the same rf voltage source as hollow cathode 12 (the rf voltage source is not shown). Alternatively, the rf voltages for the plasma-control electrode 14 and the hollow cathode 12 may be provided by separate rf voltage sources. In further embodiments variable frequency excitation means can be used, for example: audio, microwave or pulsed operation.

In this embodiment the apparatus 10 is arranged so that, during operation, reactive gas flows at least partially through the plasma region. In this specific embodiment, gas is inserted through gas inlet 24. Additionally or alternatively, gas may also be provided through any other port. For example, for the deposition of a silicon oxide/nitride coating, silane and nitrogen gases may be directed through inlet 24 and oxygen may be injected into the vacuum chamber through an additional port that is remote from the hollow cathode 12.

In this embodiment, apparatus 10 also comprises a guard wall 28. The guard wall 28 surrounds the hollow cathode 12 and thereby further confines the plasma. For example, a voltage may be applied to the guard wall 28 and the additional voltage potential can be utilised to further confine and/or control the plasma. Further, the apparatus may be arranged to generate an additional magnetic field, for example within the guard wall, that assists in confining and/or controlling the plasma.

The guard wall 28 can be used to control and/or confine the plasma by controlling and/or confining the flow of gases. In particular the geometry of the guard wall can be arranged to allow for differential pumping of the vacuum chamber and the plasma source region. For example the differential pressures may create a lower pressure in the source region and/or provide for advantageous gas flow gradients.

In this embodiment the guard wall 28 has an opening 29 that has a diameter smaller than the extension of the plasma-control electrode 14. Further, the distance between the substrate 16 and the guard wall 28 typically is 1-10 mm which usually is smaller than the distance between the substrate 16 and the cathode 12. In this embodiment, the position of the guard wall 28 and therefore the plasma controlling and/or confining properties of the guard wall can be adjustable in order to allow for different operating conditions and control surface properties.

The guard wall 28 is arranged for dedicated gas flow through port 31 using a gas supply means or pressure differential created by a pump (not shown). In this embodiment the reactive gas is supplied via gas inlet 24 and via a loop un-reacted and/or un-deposited gases can then exhaust through port 31.

In a variation of this embodiment, the flow direction of the reactant and exhaust gas is reversed, that is, reactive gas flows in through port 31 and exhaust gas is pump out via port 24. In both variations the guard wall 28 constrains the gas flow.

A further advantage of the guard wall 28 is that in this embodiment a gap is formed between the substrate 16 and the guard wall 28. To further confine the plasma, in use a gas, such an inert gas (such as Nitrogen or Argon) or another gas that does not react alone, flows through the gap formed between the guard wall 28 and the substrate 16 towards the source electrode so that the reactant gas does not diffuse significantly outside the guard wall 28 and consequently does not react significantly outside of the guard wall 28.

In a further variation of this embodiment, the reactive gas for the plasma formation may be pumped through the gap instead of, or in addition to, introducing the reactive gas through gas inlet 24 or through port 31.

In either variation the gas flow is constrained by the guard wall 28.

The apparatus 10 further comprises an optical monitoring system 30. The optical monitoring system 30 comprises an optical radiation source 32 and a detector 34. A broadband radiation is generated by the optical source 32, directed to the substrate 16 and reflections are measured by the detector 34. The detected optical signal is then analysed to obtain information about the plasma treated substrate 16 such as information about coating thickness, composition as well as optical properties of the treated substrate.

In this embodiment optical monitoring is performed outside the plasma region. Due to the confinement of the plasma by the guard wall 28 it is possible to perform the optical measurements with improved accuracy. In particular, broadband wavelength spectrum monitoring can be achieved with reduced influence from the plasma. Single or multi-wavelength monitoring is possible but broadband monitoring has the advantage that the accuracy with which the properties of the treated substrate 16 are determined can be increased. A further advantage of the optical monitoring system is that it can essentially monitor the entire substrate in real time.

Depending on the relative motion arrangement of the plasma source, substrate and plasma-control electrode, the optical monitoring system can be attached to the guard wall 28.

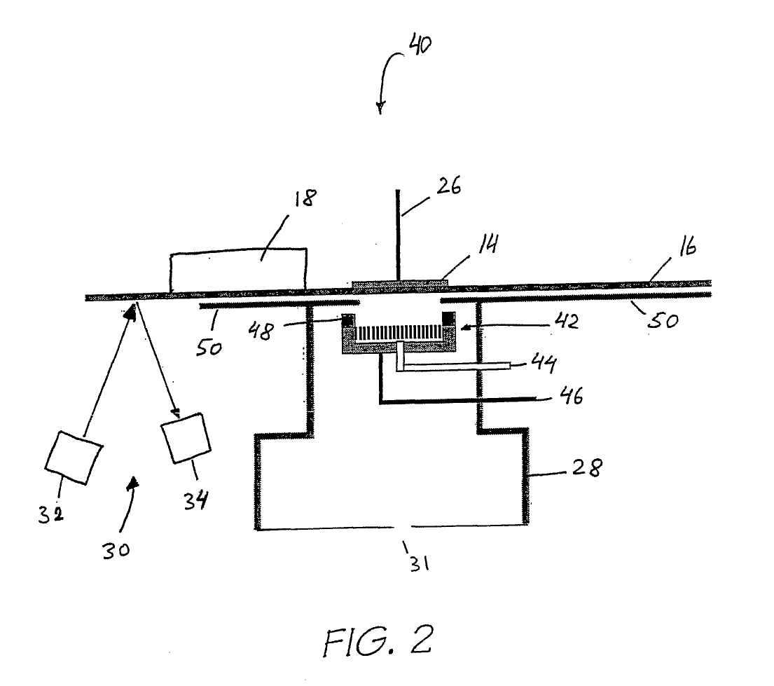

FIG. 2 shows a cross-sectional representation of an apparatus for plasma treatment of a substrate surface according to a second specific embodiment. In this case the apparatus 40 comprises a plasma source which includes “showerhead” type cathode 42 having a large number of apertures which are connected to gas inlet 44 and arranged so that gas flows in the plasma region between the cathode 42 and the substrate 16. Because of this arrangement, the gas flow is more uniform throughout the profile of the plasma.

Adjusting operating parameters such as the gas driving pressure or the shape of the showerhead, diameters of the holes or length of capillaries allows for greater flexibility in controlling the gas flow and plasma properties.

The cathode 42 has an electrical connection 46 arranged to receive an rf voltage. In order to improve the confinement of the plasma, cathode 42 has a ring-like part 48 positioned on top of cathode 42.

The guard wall 28 has extensions 50 which further improve the confinement of the plasma and can inhibit parasitic discharge. All other components of the apparatus 40 are analogous to those of the apparatus 10 shown in FIG. 1 and described above. In this embodiment the extension 50 has apertures which allow optical monitoring of the substrate 16.

Although the invention has been described with reference to particular examples, it will be appreciated by those skilled in the art that the invention may be embodied in many other forms. For example, it will be appreciated that plasma treatment is not limited to coating of substrate surfaces but may also be used to etch the substrate. This etching may be controlled in its intensity to achieve a controlled profile change of the surface.

It is to be appreciated that any type of plasma generating electrode or cathode may be used. For example, the device may comprise helicon type plasma sources or magnetron or cathodic arc plasma sources. Further, a magnetic field may be utilised to further enhance the confinement of the plasma.

In addition, the plasma-control electrode may be replaced by a fixed large sized substrate with the plasma source and guard wall moveables relative to the substrate while the guard wall confines and controls the plasma.

Further, it is to be appreciated that apparatus according embodiment of the present invention can find application in a variety of different fields. For example, the apparatus may be used for treatment of window glass for the building industry and automobiles. The apparatus may also be used in the fields of smart window production (electro-chromic coatings), passive control of energy flow (low emissivity, solar tints), strengthening of windows, antireflection coatings, dirt “repellant” coatings or treatments and water repellant coatings. In addition, the apparatus may for example be used for deposition of films and surface treatment for packaging material such as for continuous web processes including metallic coating of plastics and paper. Particular advantages of the apparatus according to embodiment of the present invention include very high throughput, source material utilization, pinhole-free layers and transparent layers. Further, the apparatus according to an embodiment of the present invention may be used for deposition of films and surface treatment during production of manufacturing/building materials. Examples include continuous web processes for deposition of corrosion protection on steel and wear coatings on steel and other basic materials.

1. An apparatus for plasma treatment of a substrate surface comprising:
a plasma source for generating a plasma,
a plasma-control electrode, and
a drive means for effecting a relative movement between the plasma-control electrode and the plasma source,
wherein in use the plasma-control electrode is located adjacent the substrate to facilitate treatment of the substrate surface in a controlled manner.

2. The apparatus as claimed in claim 1 wherein the drive means also effects in use a relative movement between the substrate and the plasma source.

3. The apparatus as claimed in claim 1 wherein the plasma-control electrode and the substrate have substantially the same size.

4. The apparatus as claimed in claim 1 wherein the substrate and the plasma-control electrode are stationary and the plasma source is driven to effect the relative movement.

5. The apparatus as claimed in claim 1 wherein the plasma source is stationary and in use both the substrate and the plasma-control electrode are driven.

6. The apparatus as claimed in claim 1 wherein the plasma source is driven and both the substrate and the plasma-control electrode are in use driven relative to the driven plasma source.

7. The apparatus as claimed in claim 6 wherein the plasma-control electrode and the substrate are in use rotated and the plasma source is in use scanning.

8. An apparatus for plasma treatment of a substrate surface comprising:
a plasma source for generating a plasma,
a plasma-control electrode, and
a drive means for effecting a relative movement of the plasma-control electrode and the plasma source relative to the substrate,
wherein in use the plasma-control electrode is located adjacent the substrate to facilitate treatment of the substrate surface in a controlled manner.

9. The apparatus as claimed in claim 8 wherein the plasma source and the plasma-control electrode are stationary and the substrate is in use driven to effect the relative movement.

10. The apparatus as claimed in claim 8 wherein the substrate is in use stationary and the plasma source and the plasma-control electrode are driven.

11. The apparatus as claimed in claim 10 wherein the plasma source and the plasma-control electrode are driven in a synchronised manner.

12. The apparatus as claimed in claim 8 wherein the substrate is in use driven and both the plasma-control electrode and the plasma source are driven relative to the driven substrate.

13. The apparatus as claimed in claim 12 wherein the substrate in use is rotated and both the plasma-control electrode and the plasma source are in use be scanning.

14. The apparatus as claimed in claim 1 wherein the plasma-control electrode is arranged for facilitating the controlled surface treatment by controlling an energy distribution of the plasma in the proximity of the surface.

15. The apparatus as claimed in claim 1 wherein the plasma-control electrode is arranged to control an energy of plasma ions impacting on the substrate.

16. The apparatus as claimed in claim 1 wherein the surface treatment is facilitated so that in use the surface is treated in a controlled and non-uniform manner.

17. The apparatus as claimed in claim 16 arranged for coating the surface in a manner so that the coating has at least one of a non-uniform thickness, density and refractive index.

18. The apparatus as claimed in claim 17 wherein the thickness, density and refractive index are tapered along a length of the substrate.

19. The apparatus as claimed in claim 1 wherein the surface treatment is facilitated so that in use the surface is treated in a controlled and uniform manner.

20. The apparatus as claimed in claim 19 arranged for coating the surface in a manner so that the coating has at least one of a uniform thickness, density and refractive index.

21. The apparatus as claimed in claim 1 wherein the plasma-control electrode is positioned so that the substrate is located between the plasma source and the plasma-control electrode.

22. The apparatus as claimed in claim 1 wherein the substrate is positioned on the plasma-control electrode.

23. The apparatus as claimed in claim 1 wherein the plasma-control electrode comprises apertures.

24. The apparatus as claimed in claim 1 wherein the plasma control electrode is a mesh.

25. The apparatus as claimed in claim 24 wherein the mesh is positioned between the plasma source and the substrate.

26. The apparatus as claimed in claim 1 arranged so that the controlled treatment of the surface is facilitated by controlling a velocity of the relative movement and whereby a local plasma treatment time per unit substrate area can be controlled.

27. The apparatus as claimed in claim 1 comprising a guard wall that confines the plasma.

28. The apparatus as claimed in claim 27 wherein the guard wall is positioned about the plasma source.

29. The apparatus as claimed in claim 27 wherein the guard wall surrounds the plasma source.

30. The apparatus as claimed in claim 27 wherein the guard wall is also arranged to control a flow of gas.

31. The apparatus as claimed in claim 27 wherein the guard wall comprises an electrically conductive material and a voltage potential is in use applied to the guard wall to further control properties of the plasma.

32. The apparatus as claimed in claim 27 wherein the guard wall in use confines the plasma to a main plasma region and reduces plasma formation outside the main plasma area.

33. The apparatus as claimed in claim 27 wherein the guard wall is positioned so that in use a gap is formed between the substrate and the guard wall.

34. The apparatus as claimed in claim 33 wherein the guard wall is arranged for pumping a gas through the gap and towards the source electrode.

35. The apparatus as claimed in claim 34 wherein a reactive gas is in use pumped through the source with its exhaust affected by the gas pumped through the gap.

36. The apparatus as claimed in claim 1 wherein the plasma source comprises a number of spaced apart gas outlets.

37. The apparatus as claimed in claim 1 further comprising a monitoring system that is arranged to monitor the plasma treated substrate.

38. The apparatus as claimed in claim 37 wherein the monitoring system is an optical system and is arranged to irradiate the substrate with a broadband optical wavelength spectrum and is also arranged to receive reflections from the plasma treated substrate.

39. The apparatus as claimed in claim 38 wherein the monitoring system and the relative movement are arranged so that the surface can be monitored during treatment but outside the plasma region to enable quasi real-time monitoring.

40. An apparatus for plasma treatment of a substrate surface comprising:
a plasma source for generating a plasma,
a drive means for effecting a relative movement of the substrate relative to the plasma source and
a guard wall positioned about the plasma source to confine the plasma,
wherein in use the relative movement effects treatment of the substrate in a predetermined manner and the guard wall confines the plasma.

41. The apparatus as claimed in claim 40 wherein the guard wall is positioned about the plasma source.

42. The apparatus as claimed in claim 41 wherein the guard wall surrounds the plasma source.

43. The apparatus as claimed in claim 40 wherein the guard wail is also arranged to confine a flow of gas.

44. The apparatus as claimed in claim 40 wherein the guard wall comprises an electrically conductive material and a voltage potential is in use applied to the guard wall to further control properties of the plasma.

45. The apparatus as claimed in claim 40 wherein the guard wall is positioned so that in use a gap is formed between the substrate and the guard wall.

46. The apparatus as claimed in claim 45 wherein the guard wall is arranged for pumping a gas through the gap and towards the source electrode.

47. A substrate that is plasma treated by the apparatus claimed in claim 1.

48. The apparatus as claimed in claim 8 wherein the plasma-control electrode is arranged for facilitating the controlled surface treatment by controlling an energy distribution of the plasma in the proximity of the surface.

49. The apparatus as claimed in claim 8 wherein the plasma-control electrode is arranged to control an energy of plasma ions impacting on the substrate.

50. The apparatus as claimed in claim 8 wherein the surface treatment is facilitated so that in use the surface is treated in a controlled and non-uniform manner.

51. The apparatus as claimed in claim 8 wherein the plasma-control electrode is positioned so that the substrate is located between the plasma source and the plasma-control electrode.

52. The apparatus as claimed in claim 8 wherein the substrate is positioned on the plasma-control electrode.

53. The apparatus as claimed in claim 8 wherein the plasma-control electrode comprises apertures.

54. The apparatus as claimed in claim 8 wherein the plasma control electrode is a mesh.

55. The apparatus as claimed in claim 8 arranged so that the controlled treatment of the surface is facilitated by controlling a velocity of the relative movement and whereby a local plasma treatment time per unit substrate area can be controlled.

56. The apparatus as claimed in claim 8 comprising a guard wall that confines the plasma.

57. The apparatus as claimed in claim 8 wherein the plasma source comprises a number of spaced apart gas outlets.

58. The apparatus as claimed in claim 8 further comprising a monitoring system that is arranged to monitor the plasma treated substrate.

59. A substrate that is plasma treated by the apparatus claimed in claim 8.
